(19) United States
(12) Patent Application Publication
(10) Pub. No.: US 2005/0093121 A1
(43) Pub. Date: May 5, 2005

(54) Chip package and substrate

(76) Inventors: Da-Jung Chen, TAOYUAN COUNTY (TW); Che-Hung Lin, YILAN COUNTY (TW); Chin-Hsiung Liao, HSINCHU COUNTY (TW); Cheng-Chieh Hsu, HSINCHU CITY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/707,865

(22) Filed: Jan. 20, 2004

(30) Foreign Application Priority Data
Nov. 5, 2003 (TW) 92130893

(51) Int. Cl. H01L 23/52

(52) U.S. Cl. 257/678

(57) ABSTRACT

A chip package comprising a substrate, a lead frame, a chip, a set of bonded wires, a heat sink and a packaging material is provided. The substrate has a first metallic layer, a second metallic layer and a conductor. The first metallic layer is formed on a first surface of the substrate and the second metallic layer is formed on a second surface of the substrate. The conductor is formed on a lateral surface of the substrate. The first metallic layer is electrically connected to the second metallic layer through the conductor. The lead frame is attached on the first surface of the substrate and is electrically connected to the first metallic layer. The chip has a back surface attached to the lead frame or the first surface of the substrate. The chip is connected with the lead frame through the bonding wires. The heat sink is attached on the second surface of the substrate and electrically connected with the second metallic layer. The packaging material encapsulates the chip, the bonded wires and the lead frame.

### CROSS REFERENCE TO RELATED APPLICATIONS

This application claims the priority benefit of Taiwan application serial no.92130893, filed on Nov. 5, 2003.

### BACKGROUND OF INVENTION

1. Field of the Invention

The present invention relates to a chip package structure and a substrate. More particularly, the present invention relates to a chip package structure having a substrate with a lateral conductor for electrically connecting a metallic layer on an upper surface of the substrate with another metallic layer on a lower surface of the substrate.

2. Description of the Related Art

In this fast and ever-changing society, electronic products for transmitting information has become indispensable. The core component of most electronic products is still a silicon chip. Through the silicon chip, logical computations are executed and data are stored in memory devices. The output power from a power source will normally pass through a high voltage power module. The power module serves as a controller for directing current flow and a switch. Because the high voltage power module has to withstand a large current or voltage loading transmitted from a power terminal, as a result the power module may generate a lot of heat. To dissipate the heat from the power module to the ambient as quickly as possible, most power module is incorporated with a heat sink.

Conventional high voltage power module has a package structure with a lead frame and a heat sink on both sides of an insulating substrate. The lead frame and the heat sink are electrically isolated. A chip is set on the lead frame and the chip is electrically connected to lead frame through wires by a wire-bonding process. Thus, heat generated by the chip can be dissipated through the lead frame, the insulating substrate and the heat sink to the ambient. In the aforementioned chip package, the heat sink serves solely as a heat-dissipating element. Yet, because the lead frame and the heat sink are electrically isolated, at least two electrodes equipped on the electroplating apparatus require connecting with the heat sink and the lead frame individually for plating the heat sink and the lead frame. Consequently, the degree of complexity in fabrication of the power module is increased.

In newer applications, the heat sink and the lead frame are electrically connected to form a ground for stabilizing the ground voltage. Since plating of the heat sink and the lead frame can be carried out after attaching electrodes to the lead frame, this type of package not only facilitates electroplating but also improves electrical performance as well. The method in which the heat sink and the lead frame are electrically connected is described below refering to FIG. 1.

FIG. 1 is a schematic cross-sectional view of a conventional high voltage power module after assembling a lead frame, an insulating substrate and a heat sink together. As shown in FIG. 1, the power module comprises an insulating substrate 110, a lead frame 120 and a heat sink 130. The lead frame 120 is attached to an upper surface 112 of the insulating substrate 110 and the heat sink 130 is attached to a lower surface 114 of the insulating substrate 110. The insulating substrate 110 has a plurality of conductive via holes 116 with metallic material 140 therein to electrically connect the heat sink and the lead frame 120 together.

In a high voltage power module, the insulating substrate 110 is typically fabricated using a low heat-resistant ceramic material such as aluminum oxide (Al₂O₃) or aluminum nitride (AlN). Thus, the via holes 116 are formed either by laser drilling after forming the insulating substrate 110 or are pre-fabricated in the insulating substrate 100. Each method has its drawbacks.

In general, forming via holes 116 in the insulating substrate 100 by the laser drilling method needs considerable time. A fumarole appearance and sputtering scoria are likely formed around the drilled holes so that bumps project from the surface of the insulating substrate 110. Therefore, a surface polishing operation needs to be conducted after the laser drilling process to remove the projecting bumps. In addition, even after the polishing treatment, some groove vestiges are still left on the surface of the insulating substrate 110. These groove vestiges may seriously affect the reliability of the insulation substrate 110. Thereafter, a thin film process, such as physical vapor deposition, chemical vapor deposition or electroplating, or a thick film process, such as screen printing, is carried out to form the metallic material layer 140 within each via hole 116. Hence, the lead frame 120 is electrically connected to the heat sink 130 via the metallic layer 140 within the via hole 116. However, the entire process is not only time-consuming but also costly.

In the pre-fabricated process, a hole punching process is carried out during the green tape stage of the substrate fabrication process. Hence, a plurality of holes passing through the green tape is formed. Thereafter, the green tape is cofired and the holes produced in the green tape stage are transformed into via holes 116 passing through the substrate 110. The aforementioned thin film process or the thick film process is carried out to fill the via holes 116 with a metallic material 140. Thus, the lead frame 120 is electrically connected to the heat sink 130 via the metallic material 140 within the via hole 116. In general, the pre-fabrication process of forming the via holes 116 is cost effective for mass production. Since the set of punch molds is rather expensive to produce, the cost per insulating substrate will be very high if just a few insulating substrates are produced in an experimental stage, for example. Moreover, the rate of contraction of the substrate 110 after the cofiring process is rather unstable so that the diameter of the via holes 116 is highly imprecise. Ultimately, this may lead to a drop in the yield of subsequent processes.

### SUMMARY OF INVENTION

Accordingly, one objective of the present invention is to provide a chip package and a substrate. A conductor on a lateral surface of the substrate electrically connects with a metallic layer on an upper surface of the substrate with another metallic layer on a lower surface of the substrate. Because there is no need to fabricate via holes, processing time and production cost are reduced. Furthermore, the electrical performance of the chip package is enhanced.

To achieve these and other advantages and in accordance with the purpose of the invention, as embodied and broadly described herein, the invention provides a chip package structure. The chip package structure mainly comprises a substrate, a lead frame, a chip, bonding wires, a heat sink and a packaging material. The substrate comprises a first metallic layer, a second metallic layer and a conductor. The first metallic layer is formed on a first surface of the substrate and the second metallic layer is formed on a second surface of the substrate. The conductor is formed on a lateral surface of the substrate. The first metallic layer is electrically connected to the second metallic layer through the conductor. The lead frame is mounted on the first surface of the substrate and is electrically connected to the first metallic layer. The chip has a back surface attached to the lead frame or the first surface of the substrate. The chip has a plurality of bonding pads on an active surface. The bonding wires connect the bonding pads on the active surface of the chip with the lead frame. The heat sink is attached on the second surface of the substrate and electrically connected with the second metallic layer. The packaging material encapsulates the chip, the bonding wires and a portion of the lead frame and the lead frame has another portion exposed to the ambient.

According to one preferred embodiment of this invention, the conductor has a composite metallic layer structure. For example, the conductor can be a two-layer structure comprising a titanium layer and a copper layer, a two-layer structure comprises a titanium-tungsten layer and a copper layer or a three-layered structure comprising a nickel layer, a chromium layer and a copper layer. The conductor has a thickness ranging from 0.1 μm to 5 μm, for example. In addition, the conductor may be fabricated using a conductive adhesive and the substrate may be fabricated using an insulating material such as ceramic, for example.

In brief, setting up a conductor on the lateral surface of a substrate to connect metallic layers on the upper and lower surface of the substrate eliminates the process of fabricating via holes. Because there is no need to fabricate via holes, processing time and production cost are reduced. Furthermore, the electrical performance of the chip package is enhanced. In addition, electrode terminals just need to be connected to the lead frame when both the heat sink and the lead frame have to be electroplated. Hence, the electroplating operation is for plating the heat sink and the lead frame is simplified.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional high voltage power module after assembling a lead frame, an insulating substrate and a heat sink together.

FIG. 2 is a schematic cross-sectional view of a chip package of a high voltage power module according to one preferred embodiment of this invention.

FIG. 3 is a schematic cross-sectional view of the lateral side of a substrate according to one preferred embodiment of this invention.

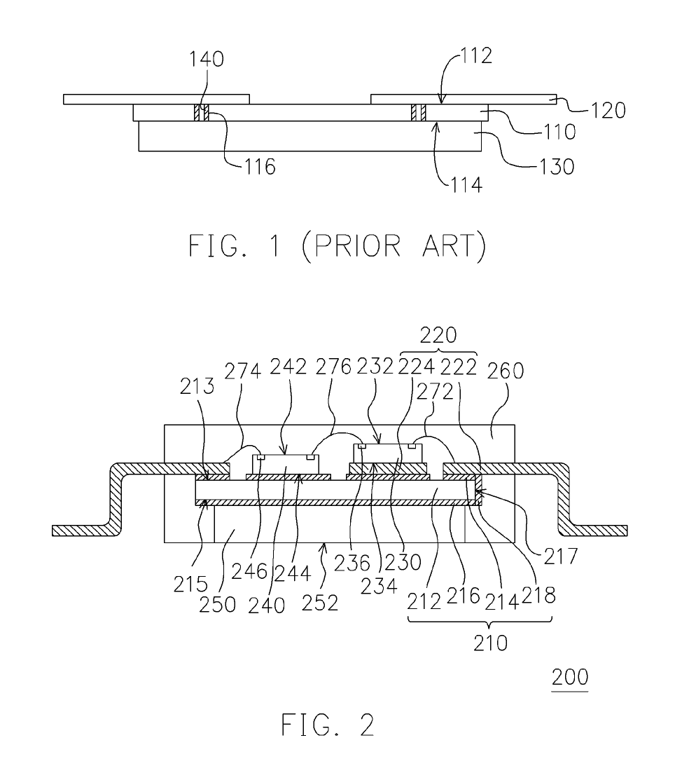

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

FIG. 2 is a schematic cross-sectional view of a chip package of a high voltage power module according to one preferred embodiment of this invention. In general, the chip package structure 200 of a high voltage power module comprises a substrate 210, a lead frame 220, a plurality of chips such as 230 and 240, a heat sink 250, packaging material 260 and a plurality of bonding wires such as 272, 274 and 276.

The substrate 210 comprises an insulating layer 212, metallic layers 214 and 216 and a conductor 218. The metallic layer 218 is formed on an upper surface 213 of the insulating layer 212 and the metallic layer 216 is formed on a lower surface 215 of the insulating layer 212. The conductor 218 is formed on a lateral surface 217 of the insulating layer 212. The metallic layers 214 and 216 are electrically connected together through the conductor 218. Ideally, the insulating layer 212 is fabricated using a low thermal resistant ceramic material, such as aluminum oxide (Al₂O₃) or aluminum nitride (AlN). The metallic layers 214, 216 and the conductor 218 are fabricated using highly electrically conductive metallic material, such as copper.

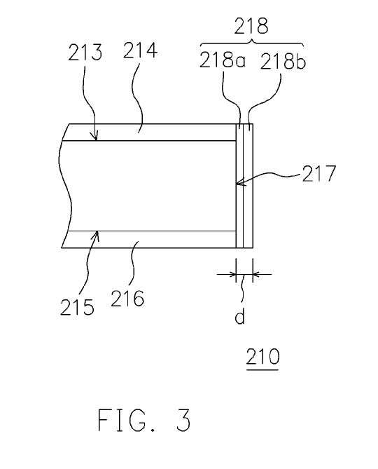

FIG. 3 is a schematic cross-sectional view of the lateral side of a substrate according to one preferred embodiment of this invention. In this embodiment, the conductor 218 can be a composite structure formed by stacking two metallic layers 218a and 218b. The internal metallic layer 218a is a titanium layer or a titanium-tungsten alloy layer, for example. The external metallic layer 218b is a copper layer, for example. To form the conductor 218, a seeding layer (the metallic layer 218a) is formed on the lateral surface 217 of the insulating layer 212 by performing a sputtering, evaporating or chemical vapor deposition process. Thereafter, an electroplating process is carried out to form the thicker metallic layer 218b over the seeding layer 218a. Preferably, the conductor 218 has a total thickness “d” between 0.1 μm and 5 μm.

However, the conductor 218 of this invention is not limited as such. The conductor can be a composite layer comprising from inside to outside three or more metallic layers. For example, the stack of metallic layers within the conductor may include a nickel layer, a chromium layer and a copper layer. The conductor can also be a single metallic layer. Alternatively, the conductor can be fabricated using a conductive adhesive, such as silver paste. To form the conductor, a roller is immersed into a pool containing a conductive adhesive and then the roller coated with the conductive adhesive is rolled over the lateral surface of the insulating layer. Afterwards, the conductive adhesive formed on the lateral surface of the insulation layer is baked and cured to form a solid conductive layer.

As shown in FIG. 2, the lead frame 220 is positioned on the upper surface 213 of the substrate 210 and is electrically connected to the metallic layer 214. In general, the lead frame 220 comprises a plurality of leads 222 and a die pad 224. The leads 222 and the die pad 224 are bonded to the metallic layer 214 through a surface mount technology (SMT) or through a conductive adhesive.

The back 234 of the chip 230 is attached to the die pad 224 of the lead frame 220 using a conductive adhesive, an insulative adhesive or a soldering material (not shown). The chip 230 has a plurality of bonding pads 236 on an active surface 232. The back 244 of the chip 240 is attached to the metallic layer 214 on the substrate 210 using a conductive adhesive, an insulative glue or a soldering material (not shown). The chip 240 has a plurality of bonding pads 246 on an active surface 242.

A wire bonding process is performed to connect the bonding pads 236 on the chip 230 with the leads 222 on the lead frame 220 using a plurality of bonding wires 272, to connect the bonding pads 246 on the chip 240 with the leads 222 on the lead frame 220 using a plurality of bonded wires 274, and to connect the bonding pads 236 on the chip 230 with the bonding pads 246 on the chip 240 using a plurality of bonded wires 276.

The heat sink 250 is attached on the lower surface 215 of the substrate 210 and is electrically connected to the metallic layer 216. The heat sink 250 is attached to the metallic layer 216 through a surface mount technology (SMT) or a conductive adhesive. Through the metallic layers 214, 216 and the conductor 218, the lead frame 220 and the heat sink 250 are electrically connected. Furthermore, the heat sink 250 may be connected to a ground terminal so that the variation in the ground voltage is attenuated. The heat sink 250 is fabricated using copper or aluminum, for example.

The packaging material 260 encapsulates the chips 230, 240, the bonded wires 272, 274, 276, the lead frame 220, the substrate 210 and the heat sink 250. However, each leads 222 of the lead frame 220 has a portion that is exposed for electrically connecting with an external circuit (not shown). Furthermore, the bottom surface 252 of the heat sink 250 is exposed or in connection with another thermal conductive structure (not shown) to boost overall heat dissipating capacity of the chip package module 200.

In conclusion, a conductor is formed on a lateral surface of the substrate to connect metallic layer on the upper and lower surface of the substrate. Because there is no need to fabricate via holes, processing time and production cost is reduced. Furthermore, electrical performance of the chip package is enhanced. In addition, for electroplating the heat sink and the lead frame, the electrode terminals just need to be connected to the lead frame. Hence, the electroplating operation for plating the heat sink and the lead frame is simplified.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A chip package structure, comprising:
a substrate, having a lateral surface, a first surface and a second surface, wherein the substrate further has a first metallic layer, a second metallic layer and a conductor with the first metallic layer located on the first surface of the substrate, the second metallic layer located on the second surface of the substrate and the conductor located on the lateral surface of the substrate, and the first metallic layer is electrically connected to the second metallic layer through the conductor;
a lead frame, located on the first surface of the substrate, wherein the lead frame is electrically connected to the first metallic layer;
a first chip, having a first active surface and a first back surface, wherein the first back surface of the first chip is bonded either onto the surface of the lead frame or onto the first surface, and the first chip has a plurality of first bonding pads on the first active surface;
a plurality of first bonding wires, connecting the first bonding pads of the first chip to the lead frame;
a heat sink, located on the second surface and electrically connected to the second metallic layer; and
a packaging material, encapsulating the first chip, the first bonding wires and a portion of the lead frame, the lead frame having another portion exposed to the ambient.

2. The chip package structure of claim 1, wherein the conductor comprises a copper layer.

3. The chip package structure of claim 1, wherein the conductor has a thickness ranging from 0.1 μm to 5 μm.

4. The chip package structure of claim 1, wherein the conductor is fabricated using a conductive adhesive.

5. The chip package structure of claim 1, wherein the process of fabricating the conductor comprises sputtering, evaporation plating, chemical vapor deposition, electroplating or coat-spreading.

6. The chip package structure of claim 1, further comprising a second chip and a plurality of second bonding wires, wherein the second chip is bonded either onto the lead frame or onto the first surface of the substrate, and the second bonding wires connects the second chip to the lead frame, and the packaging material further encapsulates the second chip and the second bonding wires.

7. The chip package structure of claim 6, further comprising a plurality of third bonding wires connecting the first chip to the second chip.

8. The chip package structure of claim 1, wherein the substrate has an insulating layer fabricated using a ceramic material.

9. A substrate structure with a lateral surface, a first surface and a second surface, comprising:
a first metallic layer, located on the first surface of the substrate;
a second metallic layer, located on the second surface of the substrate; and
a conductor, located on the lateral surface of the substrate, wherein the first metallic layer is electrically connected to the second metallic layer through the conductor.

10. The substrate structure of claim 9, wherein the conductor comprises a copper layer.

11. The substrate structure of claim 9, wherein the conductor has a thickness ranging from 0.1 μm to 5 μm.

12. The substrate structure of claim 9, wherein the conductor is fabricated using a conductive adhesive.

13. The substrate structure of claim 9, wherein the process of fabricating the conductor comprises sputtering, evaporation plating, chemical vapor deposition, electroplating or coat-spreading.

14. The substrate structure of claim 9, wherein the substrate has an insulating layer fabricated using a ceramic material.
